(19) United States
(12) Patent Application Publication
(10) Pub. No.: US 2007/0043985 A1
(43) Pub. Date: Feb. 22, 2007

(54) Memory control method and memory controller

(76) Inventor: Yuji Fujiki, Tokyo (JP)

Correspondence Address: RABIN & Berdo, PC, 1101 14TH STREET, NW, SUITE 500, WASHINGTON, DC, 20005, US

(21) Appl. No.: 11/390,060

(22) Filed: Mar. 28, 2006

(30) Foreign Application Priority Data
Jul. 27, 2005 (JP) 2005-217581

(51) Int. Cl. G01R 31/28

(52) U.S. Cl. 714/724

(57) ABSTRACT

In order to provide a memory control method and a memory controller, which can prevent an extra access even when a transfer frequency is uncertain, a memory access control method according to the invention is a method of controlling continuous transfers from a master connected to a system bus to the memory controller, wherein a transfer frequency of continuous transfers performed with respect to the memory controller is retained, and when the transfer frequency with respect to the memory controller is irregular, the transfer frequency for this time is predicted based on the retained past transfer frequency, and an access to a memory connected to the memory controller is performed first, based on the predicted transfer frequency. In other words, when the continuous access (burst transfer frequency) to the memory controller is irregular, the transfer frequency of the irregular continuous access currently performed is predicted, thereby enabling a reduction of extra access.

### CROSS REFERENCE TO RELATED APPLICATION

This application claims the priority of Application No. 2005-217581, filed on Jul. 27, 2005 in Japan, the subject matter of which is incorporated herein by reference.

### TECHNICAL FIELD OF THE INVENTION

The present invention relates to a pre-read control of an address for when a transfer frequency with respect to a memory controller is irregular.

### BACKGROUND OF THE INVENTION

In a read access, to improve performance, a memory controller which controls a main memory may predict the next address from a transfer type and a current address of a system bus connected to a CPU, a master, and the like.

In this case, if the transfer frequency is known (fixed) beforehand, an extra access can be prevented, but if the transfer frequency is uncertain, the extra access cannot be prevented. Therefore, extra power consumption increases.

In Japanese Unexamined Patent Publication No. 2004-318252, it is disclosed to perform pre-reading in read control of an SDRAM. [Patent Document 1] Japanese Unexamined Patent Publication No. 2004-318252

However, in the invention disclosed in the above document, the pre-read data is only reused as effective data as in a cache memory to improve the performance, and an extra access preventing effect cannot be obtained.

### OBJECTS OF THE INVENTION

Accordingly, an object of the present invention is to provide a memory control method and a memory controller, which can prevent an extra access when the transfer frequency is uncertain.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a memory access control method is a method of controlling continuous transfers from a master connected to a system bus to a memory controller, which comprises steps of: retaining a transfer frequency of continuous transfers performed with respect to the memory controller; predicting the transfer frequency for this time based on the retained past transfer frequency, when the transfer frequency with respect to the memory controller is irregular; and accessing a memory connected to the memory controller first, based on the predicted transfer frequency.

According to a second aspect of the present invention a memory controller controls access to an external memory from a system bus. The memory controller comprises: a transfer frequency retaining circuit which retains a transfer frequency of continuous transfers performed with respect to the memory controller; and a transfer frequency predicting circuit which predicts the transfer frequency for this time based on the retained past transfer frequency, when the transfer frequency with respect to the memory controller is irregular. The memory controller accesses the memory first, based on the transfer frequency obtained by the transfer frequency predicting circuit.

As described above, according to the present invention, when the continuous access to the memory controller (the number of burst transfers) is uncertain, the transfer frequency of irregular continuous access currently performed is predicted based on a history of the past transfer frequency, thereby enabling reduction of useless accesses. As a result, an increase in power consumption can be reduced.

### BRIEF DESCRIPTION OF THE DRAWINGS

FIG. 1 is a block diagram showing a schematic configuration of a bus system to which the present invention is applied.

FIG. 2 is a block diagram showing an overall configuration of a memory controller according to a first embodiment of the present invention.

FIG. 3 is a block diagram showing a configuration of a control signal generation block, being a main part of the memory controller according to the first embodiment.

FIG. 4 is a timing chart showing an operation in the first embodiment.

FIG. 5 is a block diagram showing an overall configuration of the memory controller according to a second embodiment of the present invention.

FIG. 6 is a block diagram showing a configuration of a “lastcnt” generation block, being the main part of the memory controller according to the second embodiment.

FIG. 7 is a block diagram showing an overall configuration of the memory controller according to a third embodiment of the present invention.

FIG. 8 is a block diagram showing a configuration of a “lastcnt” generation block, being the main part of the memory controller according to the third embodiment.

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

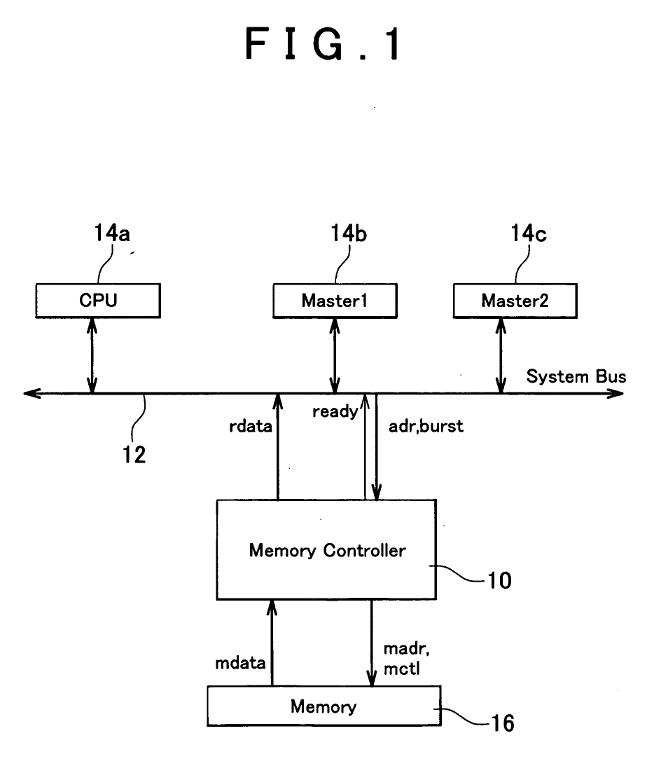

The best mode for carrying out the invention will be explained below in detail by way of examples. FIG. 1 is a block diagram showing a schematic configuration of a bus system to which the present invention is applied, wherein a plurality of masters 14a, 14b, and 14c is connected to a system bus 12, and these masters 14a, 14b, and 14c share the system bus 12. As the master, a DMA controller or the like other than a CPU can be used. A memory controller 10 which functions as a slave is connected to the system bus 12. An external memory (main memory) 16 is connected to the memory controller 10.

The system bus 12 transfers an address signal “addr” output from the respective masters (CPU (14a), master 1 (14b), master 2 (14c)), a burst signal “burst”, a response signal “ready” from the memory controller 10, and “rdata” indicating read data. The address signal “addr” indicates an address of an access destination (a memory 16), and the burst signal “burst” indicates a transfer type. The burst signal “burst” includes “FIXED” transfer in which the transfer frequency is predetermined, and “NOTFIXED” transfer in which the transfer frequency is not predetermined.

The CPU 14a, the master 1 (14b), and the master 2 (14c) using the system bus 12 output the address signal “addr” and the burst signal “burst” to the slave (memory controller) 10 via the system bus 12, when the system bus 12 is available. The memory controller 10 has a function of controlling the transfer between the external memory 16 and the system bus 12. The memory controller 10 generates an address signal “maddr” and a control signal “mctl” with respect to an access from the system bus 12, and accesses to the memory 16. The memory controller 10 also outputs read data “mdata” from the memory 16 as “rdata” for the system bus 12. Since the memory controller 10 outputs the “ready” signal indicating response completion together with the data signal “rdata”, with respect to the access from the master, the master can obtain the response timing with respect to the access request output from the own device, and the read data.

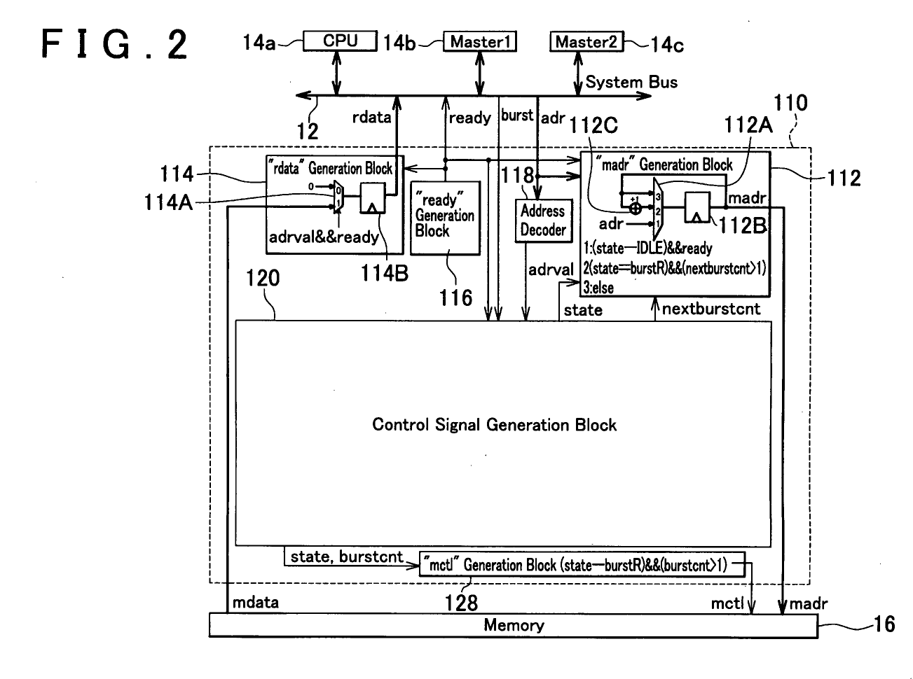

FIG. 2 is a block diagram showing a configuration of the memory controller according to a first embodiment of the present invention. A memory controller 110 in the first embodiment is used as the memory controller 10 shown in FIG. 1, and includes a “madr” generation block 112, an “rdata” generation block 114, a “ready” generation block 116, an address decoder 118, a control signal generation block 120, and a “mctl” generation block 128. The memory controller 110 is connected to the external memory 16, and has a function of controlling the transfer between the memory 16 and the system bus 12. The memory controller 110 generates signals “maddr” and “mctl” with respect to the access from the system bus 12, accesses the memory 16, and outputs the “mdata” from the memory 16 as the “rdata” for the system bus 12. For simplifying the explanation of the present invention, only the read access will be explained below, wherein mctl=H indicates read to the memory 16, and mctl=L indicates a non-read state.

In FIGS. 2, 4, and 5, symbols “==”, “&&”, “>” and “!” indicate the same meanings as in a general hardware description language (HDL). That is, “==” indicates 1 when the left side agrees with the right side, and indicates 0 when the left side does not agree with the right side. “&&” indicates a logical product. “>” indicates 1 when the left side is larger than the right side, otherwise, indicates 0. “!” indicates irregular, and indicates 1 when a subsequent signal is 0, and indicates 0 when the subsequent signal is 1.

The “madr” generation block 112 includes a selector 112A, a flip-flop circuit 112B, and an adder 112C. The “ready” signal supplied from the “ready” generation block 116, the address signal “adr” transferred from the system bus 12, a state signal “state” supplied from the control signal generation block 120, and a next transfer frequency signal “nextburstcnt” are input to the “madr” generation block 112. The “madr” generation block 112 generates the address signal “madr” with respect to the memory 16 based on these input signals.

The “rdata” generation block 114 includes a selector 114A and a flip-flop circuit 114B. The “rdata” generation block 114 generates the data signal “rdata” to be transferred to the system bus 12, based on the read data “mdata” output from the memory 16.

The “ready” generation block 116 outputs the “ready” signal, respectively, to the system bus 12, the “rdata” generation block 114, the “madr” generation block 112, and the control signal generation block 120.

The address decoder 118 decodes the address signal “adr” supplied from the system bus 12, and generates a signal “adrval” and outputs this signal to the control signal generation block 120. The signal “adrval” indicates an effective address range of the memory controller 110.

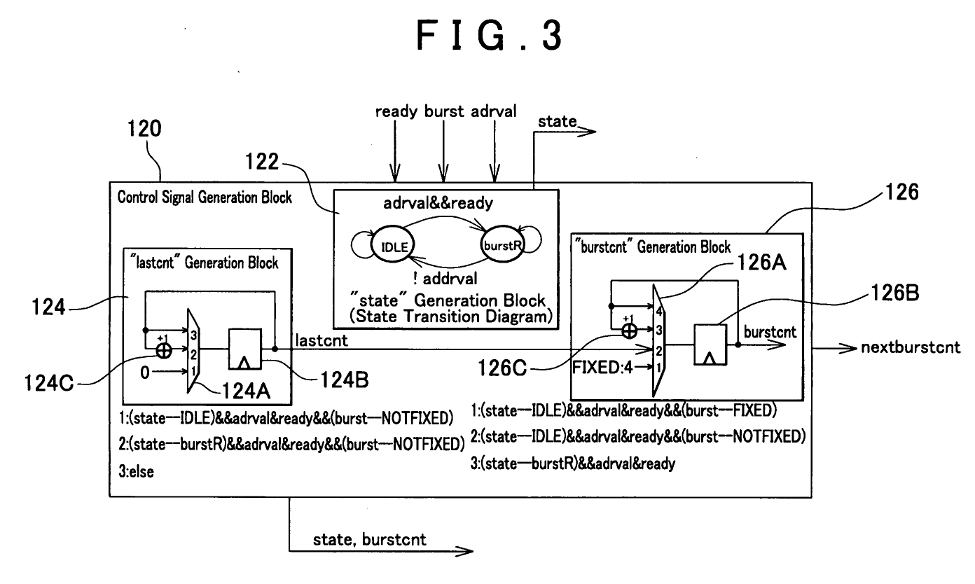

FIG. 3 is a block diagram showing a configuration of the control signal generation block 120, being a main part of the memory controller 110 according to the first embodiment. The control signal generation block 120 includes a “state” generation block 122, a “lastcnt” generation block 124, and a “burstcnt” generation block 126. The “ready” signal, the “burst” signal, and the “adrval” signal are input to the control signal generation block 120. The burst signal “burst” includes “FIXED” transfer in which the transfer frequency is predetermined, and “NOTFIXED” transfer in which the transfer frequency is not predetermined. “FIXED”=4 (four transfers) is assumed in the first embodiment.

The “state” generation block 122 is a circuit which stores a signal indicating read accessing, (adval==1) when the “adr” is effective.

The “lastcnt” generation block 124 retains the last irregular (NOTFIXED) transfer frequency, and outputs a signal “lastcnt” corresponding thereto to the “burstcnt” generation block 126. The “lastcnt” generation block 124 includes a selector 124A, a flip-flop circuit 124B, and an adder 124C. Specifically, the “lastcnt” generation block 124 stores the transfer frequency of the last “NOTFIXED” transfer frequency when the transfer frequency is uncertain (burst=NOTFIXED).

The “burstcnt” generation block 126 includes a selector 126A, a flip-flop circuit 126B, and an adder 126C. The “burstcnt” generation block 126 is a circuit which calculates an actual transfer frequency, predicts the irregular (NOTFIXED) transfer frequency “nextburstcnt” this time based on the “lastcnt” signal supplied from the “lastcnt” generation block 124, and outputs the “burstcnt” signal corresponding to the predicted value to the “mctl” generation block 128.

The “mctl” generation block 128 generates a memory control signal “mctl” for controlling the memory 16 based on the state signal “state” and the transfer type signal “burstcnt”, and outputs the memory control signal “mctl” to the memory 16.

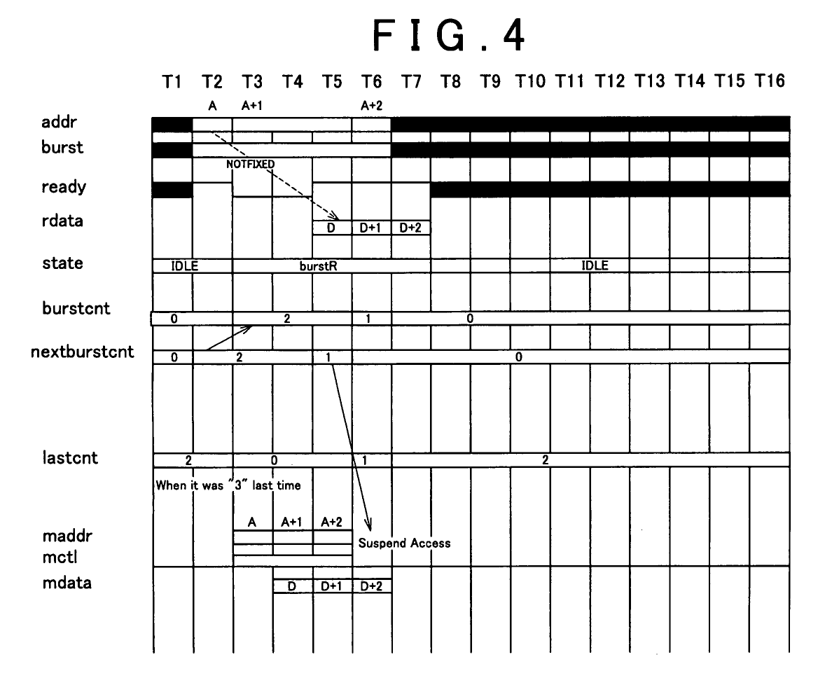

FIG. 4 is a timing chart showing an operation in the first embodiment. In the embodiment, it is assumed that the “burst==NOTFIXED” transfer with the transfer frequency being 3 has occurred heretofore. At this time, the previous time transfer frequency 3−1=2 is stored in the “lastcnt” generation block 124. In the memory controller 110 which has received the effect access “adr=A”, “burst=NOTFIXED” in T2 cycle, the selection logic of the selector 126A becomes the second one, and the memory controller 110 inputs the last transfer frequency “lastcnt”=3−1=2 to “nextburstcnt”, which is a signal in the previous stage of a storage element (the flip-flop circuit 126B) in the “burstcnt” generation block 126 by using the “lastcnt”. In T3 cycle, the “burstcnt” reflects the “nextburstcnt”. At this time, the selection logic of the selector 126A becomes the third one, and counts down the “burstcnt” sequentially for each transfer.

In T5 cycle, since the “nextburstcnt” indicates 1, it is determined that three transfers have finished, and hence, in T6 cycle, the fourth transfer is not performed. On the other hand, “lastcnt” is counted up every time “NOTFIXED” transfer is made. In T2 cycle, the selection logic of the selector 126A becomes the first one, and 0 is set in “lastcnt” in T3 cycle. In T3 and T4 cycles, the third selection logic is selected, and the value of “lastcnt” is stored. In T5 cycle, the second selection logic is selected, and “lastcnt” is counted up. Likewise, in T6 cycle, “lastcnt” is counted up. In T7 cycle, the third selection logic of the selector 124A is selected, and a value 2 corresponding to the transfer frequency being 3 is retained and used as an initial value of “burstcnt” at the time of subsequent “NOTFIXED” transfer. In the “FIXED” transfer, the value of “lastcnt” does not change, and a fixed value for “FIXED” transfer is selected as a value set in “burstcnt” at the time of starting the transfer. The “lastcnt” is used only at the time of “NOTFIXED” transfer.

In the case of “FIXED” transfer, the selector 126A selects the first selection logic, and transfer frequency 4 in the “FIXED” transfer is set to “burstcnt”. The “burstcnt” is counted down by 1 for each transfer as in the “NOTFIXED” transfer. The “mctl” generation block 128 generates a “mctl” signal based on “burstcnt”. At this time, “lastcnt” is not changed, and retains the current value.

In the “maddr” generation block 112, the selector 112A outputs any one value of the initial value “adr” (first selection logic), the current “maddr” +1 (second selection logic), and retainment (third selection logic).

The “rdata” generation block 114 performs an operation for returning “mdata” from the memory 16 as “rdata” for the system bus 12.

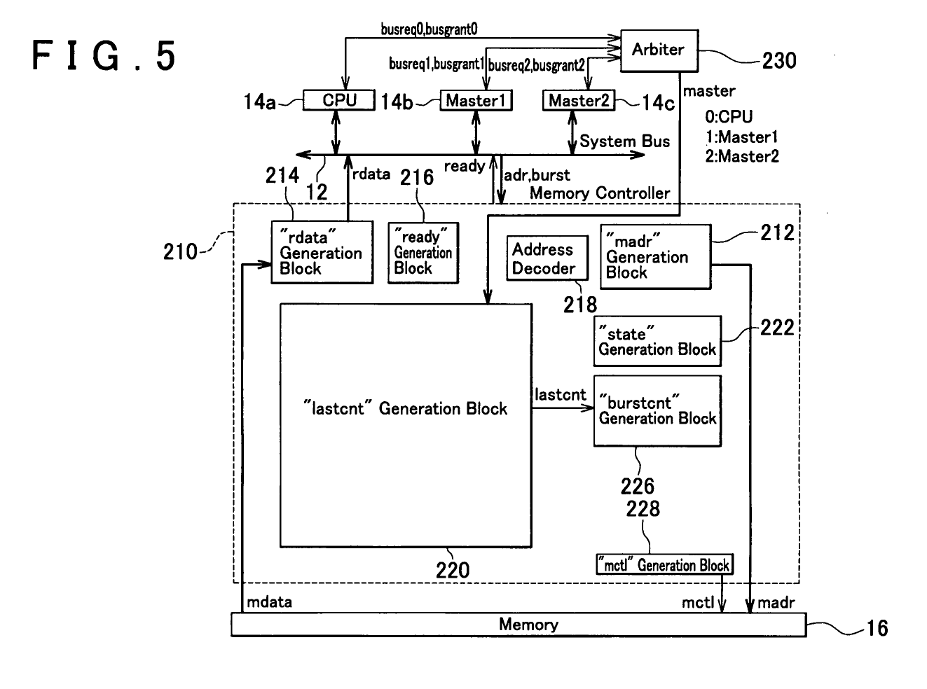

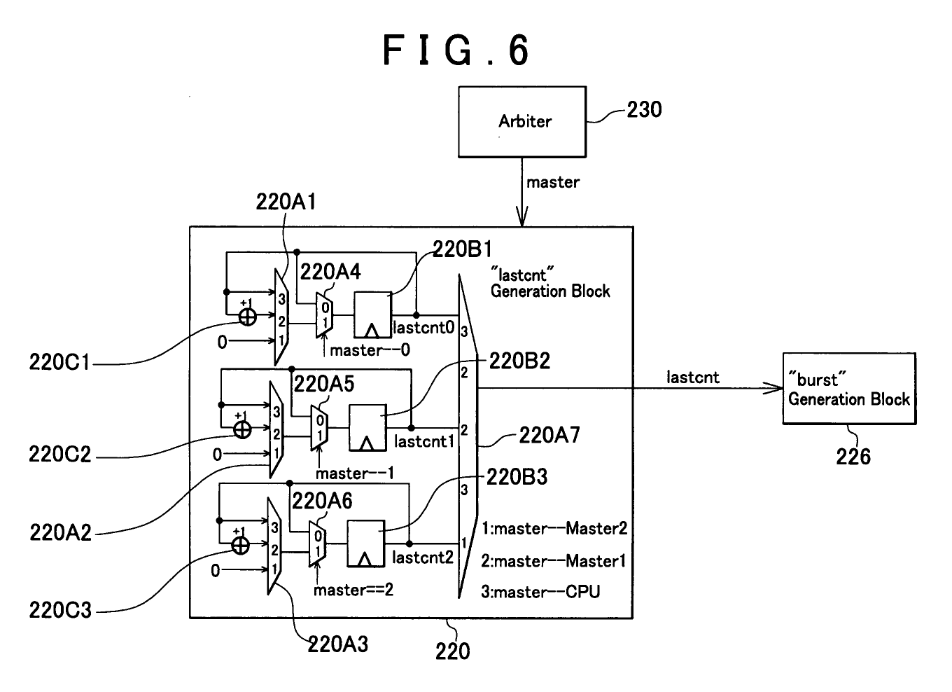

FIG. 5 is a block diagram showing a configuration of the memory controller according to a second embodiment of the present invention. FIG. 6 is a block diagram showing a configuration of the “lastcnt” generation block, being the main part of the memory controller according to the second embodiment. In FIGS. 5 and 6, like reference symbols refer to like parts as in FIGS. 2 and 3, and duplicate explanation is omitted. As for the components (212, 222, 226, and 228) corresponding to the first embodiment, since a similar configuration can be adopted, these components are simplified, and duplicate explanation is omitted. Furthermore, as for the operation in the second embodiment, parts other than those parts explained below are the same as in the first embodiment, and hence, the explanation thereof is omitted.

In the second embodiment, at the time of continuous transfer in which the transfer frequency is uncertain (irregular), the past history is read for each master by pre-read control of the memory controller in a system having a plurality of masters, to determine a frequency of continuous transfers, thereby preventing extra pre-read accesses.

A memory controller 210 in the second embodiment is used as the memory controller 10 shown in FIG. 1, and includes a “madr” generation block 212, a “rdata” generation block 214, a “ready” generation block 216, an address decoder 218, a “lastcnt” generation block 220, a “state” generation block 222, a “burstcnt” generation block 226, and a “mctl” generation block 228.

Here, to avoid redundant explanation, the differences to the aforementioned first embodiment are focused on in the explanation. At first, “busreq0”, “busreq1”, “busreq2”, “busgrant0”, “busgrant1”, “busgrant2”, and “master” signals will be explained. In FIG. 5, the CPU 14a, the master 1 (14b), the master 2 (14c), and the memory controller 210 are connected to the system bus 12. The CPU 14a, the master 1 (14b), and the master 2 (14c) make a use request of the system bus 12 to an arbiter (arbitration circuit) 230, respectively, as “busreq0”, “busreq1”, and “busreq2”.

Upon reception of the request, the arbiter 230 gives an enabling signal to use the system bus 12, to one master. The respective signals “busgrant0”, “busgrant1”, and “busgrant2” correspond to the enabling signal with respect to the CPU 14a, the master 1 (14b), and the master 2 (14c). The master having received the enabling signal is given an authority to use the system bus 12. The signal “master” output by the arbiter 230 is a value capable of discriminating which master is currently using the system bus 12. The signal “master” can be easily generated by the arbiter 230. When the signal “master” is 0, the CPU 14a, when the signal “master” is 1, the master 1 (14b), and when the signal “master” is 1, the master 2 (14c) can use the system bus 12.

The “lastcnt” generation block 220 includes selectors 220A1 to 220A7, flip-flop circuits 220B1 to 220B3, and adders 220C1 to 220C3. The selectors 220A1, 220A4, the flip-flop circuit 220B1, and the adder 220C1 function as one unit for the CPU 14a. The selectors 220A2, 220A5, the flip-flop circuit 220B2, and the adder 220C2 function as one unit for the master 1 (14b). The selectors 220A3, 220A6, the flip-flop circuit 220B3, and the adder 220C3 function as one unit for the master 1 (14b). The output of the respective units are input to the selector 220A7.

In the memory controller 210 according to the second embodiment, the “master” signal and the “lastcnt” generation block are different from those in the first embodiment. A signal “lastcnt0” indicates the last “NOTFIXED” transfer frequency of the CPU (master=0), a signal “lastcnt1” indicates the last “NOTFIXED” transfer frequency of the master 1 (master=1), and a signal “lastcnt2” indicates the last “NOTFIXED” transfer frequency of the master 2. Since the last “NOTFIXED” transfer frequency is stored for each master, prediction accuracy of the transfer frequency in which the transfer frequency is irregular is increased. The selectors 220A1, 220A2, and 220A3 have the same configuration as that of the selector 124A. However, the selectors 220A4, 220A5, and 220A6 operate for each master, to store the last “NOTFIXED” transfer frequency for each master.

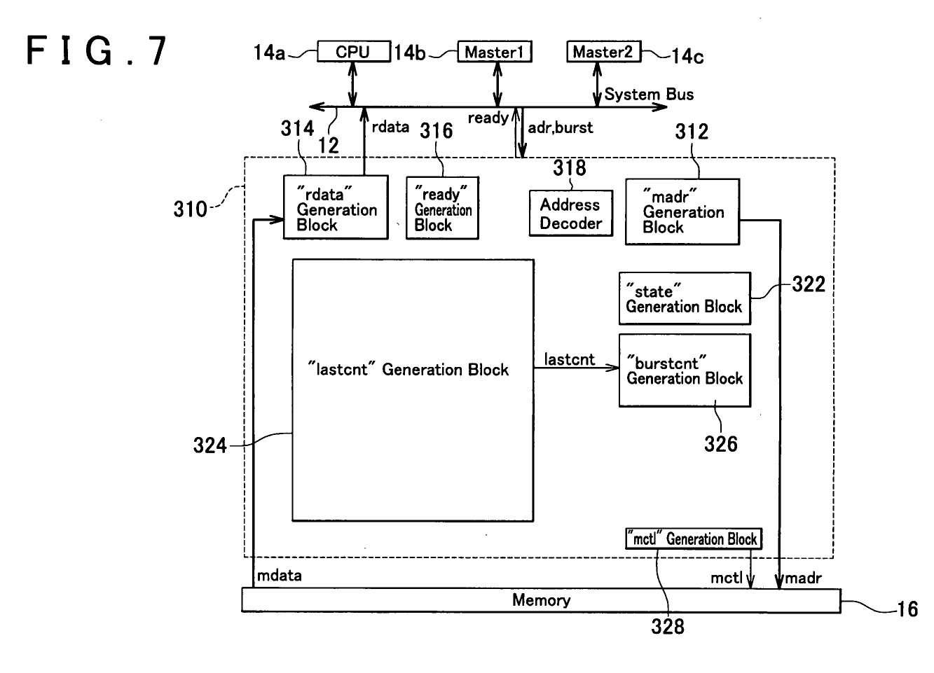

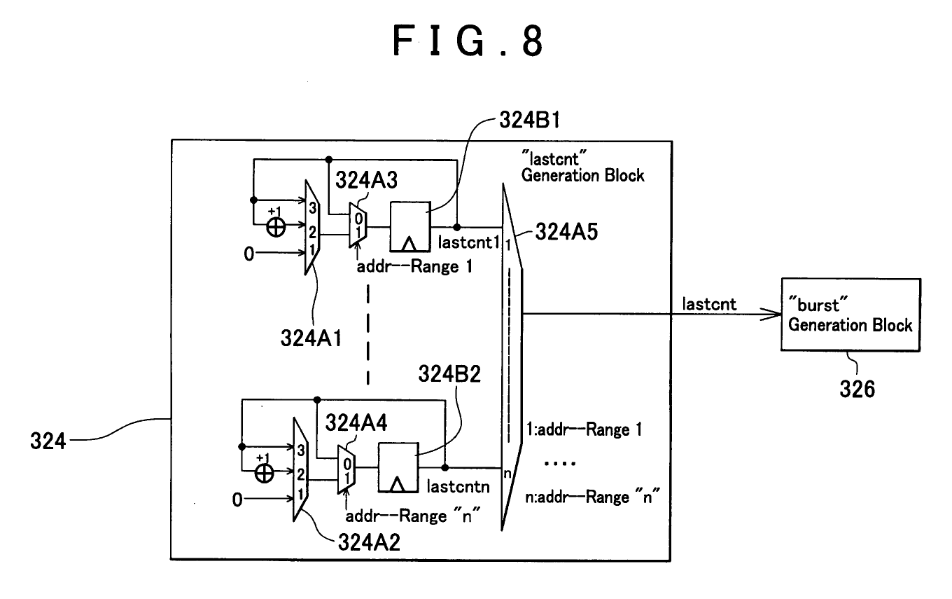

FIG. 7 is a block diagram showing a configuration of the memory controller according to a third embodiment of the present invention. FIG. 8 is a block diagram showing a configuration of the “lastcnt” generation block, being the main part of the memory controller according to the third embodiment. In FIGS. 7 and 8, like reference symbols refer to like parts as in FIGS. 2 to 6, and duplicate explanation is omitted. As for the components (312, 322, 326, 328) corresponding to the first embodiment, since a similar configuration can be adopted, these components are simplified, and duplicate explanation is omitted. Furthermore, as for the operation in the third embodiment, parts other than those parts explained below are the same as in the first embodiment, and hence, the explanation thereof is omitted.

In the third embodiment, at the time of continuous transfer in which the transfer frequency is uncertain, the past history is read for each address by pre-read control of a memory controller 310, to determine a frequency of continuous transfers, thereby preventing extra pre-read accesses. In the third embodiment, an address range which is covered by the memory controller 310 is divided into a plurality of numbers, and the frequency of transfer in which the transfer frequency is irregular is predicted for each divided range.

A main difference between the third embodiment and the first embodiment is the configuration of a “lastcnt” generation block 324. In the third embodiment, a case in which the address range covered by the memory controller 310 is divided into 1 to n is shown. The selectors 324A and 324A2 have the same configuration as that of the selector 124A in the first embodiment. The selectors 324A3 and 324A4 operate for each divided address range and retain “lastcnti” (i is 1 to n), except of a determined address range. For example, in the case of the “NOTFIXED” transfer for an address range 1, the selection logic of the selector 324A becomes 1, and “lastcnt1” is calculated as in the first embodiment. At this time, the “NOTFIXED” transfer frequency is recounted as in the first embodiment, and stored in “lastcnt1”. The third embodiment is particularly effective when the “NOTFIXED” transfer frequency is different for each address range.

The embodiments of the present invention have been explained above, but the present invention is not limited thereto, and the design can be appropriately changed within the scope of the technical concepts indicated by the claims.

In the present invention, “transfer frequency is irregular” stands for a case in which the burst signal at the time of burst transfer does not indicate a specific frequency. The transfer frequency can be predicted at the time of effective access and reception of the burst signal. Moreover, “prediction based on the past transfer frequency” may be performed by employing various forms based the past history, such as employing a value based on the previous transfer frequency (the same value or the like), or taking a mean value of the past several transfer frequencies.

The present invention is particularly effective for the burst transfer in which the access address of the memory is regular. Here if only the transfer history in the case of irregular transfer frequency is retained, the circuit configuration can be simplified.

In the case in which a plurality of masters is connected to the system bus, it is preferable to retain and predict the transfer frequency for each of the plurality of masters. As a result, the prediction accuracy of the transfer frequency can be improved, and power consumption can be reduced.

As another method of improving the prediction accuracy of the transfer frequency, transfer frequency can be retained and predicted for each predetermined range of the address of the memory controlled by the memory controller. As a result, the prediction accuracy of the transfer frequency can be further improved, and power consumption can be reduced.

What is claimed is:

1. A method of controlling continuous transfers from a master connected to a system bus to a memory controller, comprising:
retaining a transfer frequency of continuous transfers performed with respect to the memory controller;
predicting the transfer frequency for this time based on said retained past transfer frequency, when the transfer frequency with respect to said memory controller is irregular; and
accessing a memory connected to said memory controller first, based on the predicted transfer frequency.

2. A control method according to claim 1, wherein
the transfer frequency is retained only when the transfer frequency is irregular.

3. A control method according to claim 1, wherein
a transfer request to said memory controller is made by a plurality of masters connected said system bus.

4. A control method according to claim 3, wherein
the transfer frequency is retained and predicted for each of the plurality of masters.

5. A control method according to claim 4, wherein
the transfer frequency is retained only when the transfer frequency is irregular.

6. A control method according to claim 1, wherein
the transfer frequency is retained and predicted for each predetermined range of address of said memory.

7. A control method according to claim 6, wherein
the transfer frequency is retained only when the transfer frequency is irregular.

8. A memory controller which controls access to an external memory from a system bus, comprising:
a transfer frequency retaining circuit which retains a transfer frequency of continuous transfers performed with respect to said memory controller; and
a transfer frequency predicting circuit which predicts the transfer frequency for this time based on said retained past transfer frequency, when the transfer frequency with respect to said memory controller is irregular, wherein
said memory controller accesses the memory first, based on the transfer frequency obtained by said transfer frequency predicting circuit.

9. A memory controller according to claim 8, wherein
said transfer frequency retaining circuit has such a configuration as to retain the transfer frequency when the transfer frequency is irregular.

10. A memory controller according to claim 8, wherein a plurality of masters is connected to said system bus, so that access requests from these masters are processed alternatively.

11. A memory controller according to claim 10, wherein
said transfer frequency retaining circuit and said transfer frequency predicting circuit are provided, respectively, for each of said plurality of masters.

12. A memory controller according to claim 10, wherein
said transfer frequency retaining circuit has such a configuration as to retain the transfer frequency when the transfer frequency is irregular.

13. A memory controller according to claim 8, wherein
said transfer frequency retaining circuit and said transfer frequency predicting circuit respectively retains and predicts the transfer frequency for each predetermined range of said address of said memory.

14. A memory controller according to claim 13, wherein
said transfer frequency retaining circuit has such a configuration as to retain the transfer frequency when the transfer frequency is irregular.
